(19) United States
(12) Patent Application Publication
(10) Pub. No.: US 2023/0069139 A1
(43) Pub. Date: Mar. 2, 2023

(54) CVD APPARATUS AND METHOD FOR CLEANING CHAMBER OF CVD APPARATUS

(71) Applicant: ASM IP Holding B.V., Almere (NL)

(72) Inventors: Ippei Yanagisawa, Sagamihara-shi (JP); Chiao Yin Nien, Yokohama-shi (JP)

(21) Appl. No.: 17/896,218

(22) Filed: Aug. 26, 2022

Related U.S. Application Data
(60) Provisional application No. 63/238,532, filed on Aug. 30, 2021.

(51) Int. Cl. C23C 16/44; C23C 16/513

(52) U.S. Cl. CPC C23C 16/4405; C23C 16/513

(57) ABSTRACT

A CVD apparatus includes a chamber, a susceptor, an entry/takeout port for a substrate, and a gate valve provided at the entry/takeout port, in which the susceptor has a mounting plate and a support, the entry/takeout port is provided on a part of a side of the chamber, and is provided in a range from an inner bottom surface of the chamber to a position corresponding to the lower surface of the mounting plate when the susceptor is located at an upper end in the vertical direction, and the inner bottom surface of the chamber, the range from the inner bottom surface of the chamber to the position corresponding to the lower surface of the mounting plate when the susceptor is located at the upper end in the vertical direction, the lower surface of the mounting plate, and the outer side surface of the support are coated with ceramic liners.

### CROSS-REFERENCE TO RELATED APPLICATIONS

This application claims priority to U.S. Provisional Patent Application Ser. No. 63/238,532 filed Aug. 30, 2021 titled CVD APPARATUS AND METHOD FOR CLEANING CHAMBER OF CVD APPARATUS, the disclosure of which is hereby incorporated by reference in its entirety.

### BACKGROUND OF THE INVENTION

### Field of the Invention

The present disclosure relates to a CVD apparatus and a method for cleaning a chamber of a CVD apparatus.

### Description of Related Art

The CVD apparatus is known as a thin film forming apparatus that forms a thin film by depositing a substance generated by a chemical reaction of a source gas containing a thin film component on the surface of a substrate. As the CVD apparatus, a plasma CVD apparatus is widely used. In a plasma CVD apparatus, a chemical reaction is promoted by exciting a source gas into a plasma state and generating active excited molecules, radicals, and ions. In the plasma CVD apparatus, a susceptor for supporting a substrate (for example, a silicon wafer) to be film-deposited is arranged in a chamber. A shower head for supplying a source gas to the inside of the chamber is arranged above the susceptor. Plasma is generated by applying a radio frequency (RF) voltage between the shower head and the susceptor.

In the CVD apparatus, film components may be deposited on the inner wall surface of the chamber and the surface of the susceptor due to the film formation. When the film thickness of the deposits of this film component becomes thick, the deposits may be separated from the inner wall surface of the chamber or the surface of the susceptor to become particles and adhere to the substrate to be treated or the thin film formed. Therefore, in order to remove the deposits inside the chamber, it is necessary to clean the chamber. As a chamber cleaning method, a method using two types of cleaning gases, a first cleaning gas and a second cleaning gas, is known (see, U.S. Pat. No. 6,843,858). As the first cleaning gas, a gas containing a fluorine compound is used, and as the second cleaning gas, a gas containing hydrogen, argon, an oxygen source, a fluorine compound and the like is used.

As a method of removing deposits in the chamber of the CVD apparatus, a method of using a cleaning gas containing a fluorine compound is effective. However, since the chamber is formed using a metal material such as aluminum, when a cleaning gas containing a fluorine compound is used, the metal inside the chamber reacts with the cleaning gas to generate a metal compound such as metal fluorides. When repeated cleaning is performed using a cleaning gas, metal compounds may be accumulated on the inner wall surface of the chamber, and the accumulated metal compounds may be separated from the inner wall surface of the chamber to become particles to adhere to the substrate to be processed or the thin film formed.

### SUMMARY OF THE INVENTION

A first aspect of the present disclosure provides a CVD apparatus including a chamber, a cleaning gas supply pipe that supplies a cleaning gas to the chamber and an oxygen-containing gas supply pipe that supplies an oxygen-containing gas to the chamber, wherein the cleaning gas supply pipe has a first valve, the oxygen-containing gas supply pipe has a second valve, after the first valve is opened to supply the cleaning gas to the inside of the chamber, the second valve is opened to supply the oxygen-containing gas to the inside of the chamber with the first valve closed.

The CVD apparatus according to the aspect may include a source gas supply pipe that supplies a source gas to the chamber, wherein the source gas supply pipe, the cleaning gas supply pipe, and the oxygen-containing gas supply pipe may be each connected to the chamber via a gas supply pipe.

In the CVD apparatus according to the aspect, the cleaning gas supply pipe and the oxygen-containing gas supply pipe may include a remote plasma unit.

In the CVD apparatus according to the aspect, the oxygen-containing gas may contain oxygen and an inert gas.

In the CVD apparatus according to the aspect, the oxygen concentration of the oxygen-containing gas may be in the range of 40% by volume or more and 60% by volume or less.

In the CVD apparatus according to the aspect, the cleaning gas may be a fluorine-containing gas.

In the CVD apparatus according to the aspect, the fluorine-containing gas may contain a fluorine compound gas and an inert gas.

In the CVD apparatus according to the aspect, a gas outlet may be arranged along the inner wall surface of the chamber.

A second aspect of the present disclosure provides a method for cleaning a chamber of a CVD apparatus, including the following steps, a step of supplying a cleaning gas to the chamber, a step of stopping the supply of the cleaning gas to the chamber and supplying the oxygen-containing gas to the chamber.

In the method for cleaning a chamber of a CVD apparatus, the oxygen-containing gas may be supplied at a flow rate equal to or higher than the flow rate of the cleaning gas.

In the method for cleaning a chamber of a CVD apparatus, the oxygen-containing gas may be supplied for 50% or less of the supply time of the cleaning gas.

### BRIEF DESCRIPTION OF THE DRAWINGS

FIG. 1 is a schematic configuration diagram of a CVD apparatus according to one embodiment of the present disclosure.

FIG. 2 is a schematic configuration diagram showing a state of an example when cleaning the chamber of the CVD apparatus shown in FIG. 1.

FIG. 3 is a cross-sectional view taken along the line of FIG. 2.

FIG. 4 shows the results of elemental analysis of deposits inside the chamber after film formation and cleaning are repeated, which were measured in Example 1.

### DETAILED DESCRIPTION OF THE INVENTION

Hereinafter, the present disclosure will be described in detail with reference to the drawings as appropriate. The drawings used in the following description may be enlarged for convenience in order to make the features of the present disclosure easy to understand, and the dimensional ratio of each component may differ from the actual one. The materials, dimensions, etc. exemplified in the following description are examples, and the present disclosure is not limited thereto and it is possible to appropriately change and implement the present disclosure within a range in which the effects of the present disclosure can be obtained.

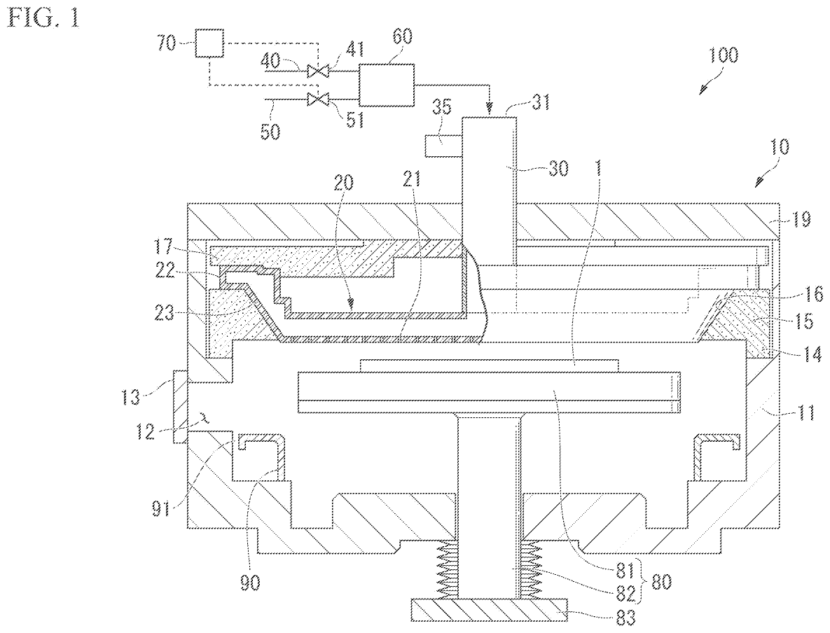

FIG. 1 is a schematic configuration diagram of a CVD apparatus according to an embodiment of the present disclosure. As shown in FIG. 1, the CVD apparatus 100 of the present embodiment includes a chamber 10, a source gas supply pipe 35 that supplies a source gas to the chamber 10, a cleaning gas supply pipe 40 that supplies a cleaning gas to the chamber 10, and an oxygen-containing gas supply pipe 50 that supplies an oxygen-containing gas to the chamber 10. In FIG. 1, the chamber 10 is a partial cross-sectional view.

The chamber 10 is a substantially cylindrical body. The chamber 10 includes a chamber body 11 and a lid member 19. The chamber body 11 and the lid member 19 are made of a metal material. As the metal material, for example, aluminum can be used.

An entry/takeout port 12 for a substrate 1 to be processed is provided on the side of the chamber body 11. The entry/takeout port 12 can be opened and closed by a door member 13. A recess 14 is provided on the inner wall surface of the chamber body 11 above the entry/takeout port 12. A shower head fixing member 15 is arranged in the recess 14. The shower head fixing member 15 is a ring-shaped member having a reversed conical opening 16 in which the diameter below is smaller than the diameter above. As the material of the shower head fixing member 15, for example, a ceramic material such as Al₂O₃ can be used.

The shower head 20 has a large number of vents 21 at the bottom thereof. The upper portion of the shower head 20 has a flange portion 22 which diameter is larger than the diameter of the opening of the shower head fixing member 15. In the shower head 20, the side portion below the flange portion 22 has a reversed conical side surface 23 having a lower outer peripheral diameter smaller than the upper outer peripheral diameter. The side surface 23 of the shower head 20 and the opening 16 of the shower head fixing member 15 are formed so as to be in close contact with each other. As the material of the shower head 20, for example, a metal such as aluminum can be used.

A high-frequency shielding plate 17 is arranged between the shower head 20 and the lid member 19. As the material of the high frequency shielding plate 17, for example, a ceramic material such as Al₂O₃ can be used.

The upper center of the shower head 20 is connected to a gas supply pipe 30. The side portion of the gas supply pipe 30 is connected to the source gas supply pipe 35. The upper portion 31 of the gas supply pipe 30 is connected to a RPU (remote plasma unit) 60. The RPU 60 is connected to the cleaning gas supply pipe 40 and the oxygen-containing gas supply pipe 50. The RPU 60 turns the cleaning gas and the oxygen-containing gas into plasma. The cleaning gas activates its cleaning power by being turned into plasma. The oxygen-containing gas activates its oxidizing power by being turned into plasma. The cleaning gas supply pipe 40 has a first valve 41, and the oxygen-containing gas supply pipe 50 has a second valve 51. The opening and closing of the first valve 41 and the second valve 51 is controlled by the controller 70. The controller 70 controls to open the first valve 41 to supply cleaning gas to the inside of the chamber 10, and then to open the second valve 51 to supply oxygen-containing gas to the inside of the chamber 10 with the first valve 41 closed.

As the cleaning gas flowing through the cleaning gas supply pipe 40, for example, a fluorine-containing gas can be used. The fluorine-containing gas may be a mixed gas containing a fluorine compound gas and an inert gas. As the fluorine compound gas, for example, nitrogen trifluoride gas (NF₃) and fluorocarbon gas (CxFy) can be used. As the inert gas, for example, helium gas, argon gas, and nitrogen gas can be used. The cleaning gas may contain oxygen. Each of these fluorine compound gas and the inert gas may be used alone or in combination of two or more.

The oxygen-containing gas flowing through the oxygen-containing gas supply pipe 50 may be a mixed gas containing oxygen and an inert gas. The oxygen concentration of the oxygen-containing gas may be in the range of 40% by volume or more and 60% by volume or less. As the inert gas, for example, helium gas, argon gas, and nitrogen gas can be used. These inert gases may be used alone or in combination of two or more.

A susceptor 80 is arranged inside the chamber 10. The susceptor 80 has a mounting plate 81 and a support rod 82 that supports the mounting plate 81. The substrate 1 to be processed is mounted on the upper surface of the mounting plate 81. A lift mechanism 83 is provided below the support rod 82, and the lift mechanism 83 is configured to move the susceptor 80 in the vertical direction. The mounting plate 81 and the support rod 82 of the susceptor 80 are made of a metal material such as aluminum.

A gas exhaust pipe 90 having a gas discharge port 91 is arranged inside the chamber 10. The gas discharge port 91 is arranged along the inner wall surface of the chamber 10.

A method of forming a thin film using the CVD apparatus 100 of FIG. 1 will be described. The substrate 1 to be processed is placed on the upper surface of the mounting plate 81 of the susceptor 80, and the susceptor 80 is moved to a predetermined position by using the lift mechanism 83. Next, the source gas is supplied from the source gas supply pipe 35 to the shower head 20 via the gas supply pipe 30, and the source gas is discharged from the ventilation holes 21 toward the substrate 1 to be processed. Next, a high frequency (RF) voltage is applied between the shower head 20 and the mounting plate 81 of the susceptor 80 using a high frequency power source (not shown) to bring the source gas into a plasma state. As a result, active excited molecules, radicals, and ions are generated, the chemical reaction is promoted, and a thin film is formed on the surface of the substrate 1 to be treated.

After the thin film is formed on the surface of the substrate 1 to be processed, the supply of the source gas is stopped. Next, the susceptor 80 is lowered by the lift mechanism 83, and the mounting plate 81 is moved to the position of the entry/takeout port 12. After that, the door member 13 is moved to open the entry/takeout port 12, and the substrate 1 to be processed is taken out from the entry/takeout port 12.

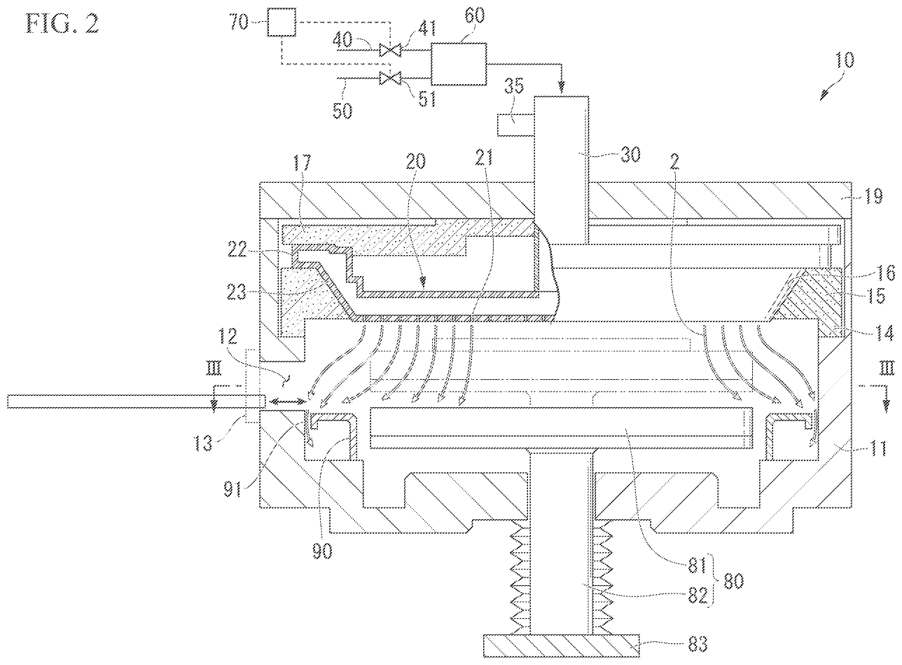

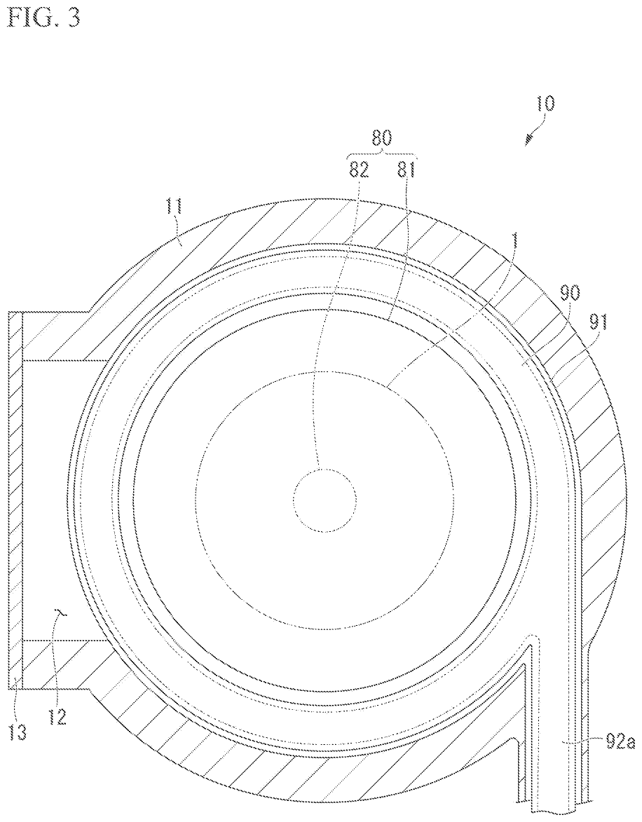

Next, a method for cleaning the chamber 10 of the present embodiment will be described. FIG. 2 is a schematic configuration diagram showing a state of an example when cleaning the chamber of the CVD apparatus shown in FIG. 1. FIG. 3 is a cross-sectional view taken along the line of FIG. 2. In FIG. 2, the cleaning of the chamber 10 is performed in a state where the substrate 1 to be processed is taken out from the entry/takeout port 12, that is, in a state where the susceptor 80 is lowered. Cleaning of the chamber 10 is performed as follows.

First, the first valve 41 is opened to supply the cleaning gas 2 to the inside of the chamber 10 as shown in FIG. 2. By opening the first valve 41, the cleaning gas is sent from the upper portion 31 of the gas supply pipe 30 to the gas supply pipe 30 in a state where the cleaning gas is turned into plasma by the RPU 60 and the cleaning power is activated. The cleaning gas 2 sent to the gas supply pipe 30 is supplied to the shower head 20 and discharged into the chamber 10 through the ventilation holes 21. The cleaning gas 2 released into the chamber 10 flows along the inner wall surface of the chamber 10 and the surface of the susceptor 80. As a result, the cleaning gas 2 removes the deposits of the thin film components deposited on the inner wall surface of the chamber 10 and the surface of the susceptor 80, and a part of the metal contained in the inner wall surface of the chamber 10 and the susceptor 80 reacts with the cleaning gas 2 to generate a metal compound. After that, the cleaning gas 2 flows to the gas exhaust pipe 90 through the gas discharge port 91, and is then taken out from a gas outlet 92 (see FIG. 3). Since the gas discharge port 91 is arranged along the inner wall surface of the chamber 10, the cleaning gas 2 easily flows along the inner wall surface of the chamber 10.

The flow rate of the cleaning gas 2 supplied to the inside of the chamber 10 is, for example, in the range of 0.1 slpm (standard liter per minute) or more and 10 slpm or less. The supply time of the cleaning gas 2 is, for example, in the range of 20 seconds or more and 300 seconds or less.

Next, with the first valve 41 closed and the supply of the cleaning gas 2 to the inside of the chamber 10 stopped, the second valve 51 is opened to supply the oxygen-containing gas to the inside of the chamber 10. By opening the second valve 51, the oxygen-containing gas is turned into plasma by the RPU 60 and sent to the gas supply pipe 30 via the upper portion 31 of the gas supply pipe 30 in a state where the oxidizing power is activated. The oxygen-containing gas sent to the gas supply pipe 30 is supplied to the shower head 20 and is discharged into the chamber 10 through the ventilation holes 21. The oxygen-containing gas released into the chamber 10 flows along the inner wall surface of the chamber 10 and the surface of the susceptor 80, as in the case of the cleaning gas 2 shown in FIG. 2. As a result, the metal compound formed on the inner wall surface of the chamber 10 and the surface of the susceptor 80 is partially oxidized. Therefore, in the chamber 10 cleaned by the cleaning method of the chamber 10 of the present embodiment, a complex oxide such as a fluoride oxide is generated on the inner wall surface and the surface of the susceptor 80.

The flow rate of the oxygen-containing gas supplied to the inside of the chamber 10 is, for example, in the range of 2 times or more and 10 times or less the flow rate of the cleaning gas. The flow rate of the oxygen-containing gas may be equal to or higher than the flow rate of the cleaning gas. The supply time of the oxygen-containing gas is, for example, within the range of 1/10 or more and ½ or less of the cleaning time.

As described above, after the chamber 10 is cleaned, the door member 13 is moved to open the entry/takeout port 12, and the substrate 1 to be processed is arranged on the mounting plate 81 of the susceptor 80 from the entry/takeout port 12. Next, the susceptor 80 is moved to a predetermined position using the lift mechanism 83 to carry out film formation. The cleaning of the chamber 10 may be performed every time the film formation is performed, or may be performed after the film formation is performed a plurality of times.

In the CVD device 100 of the present embodiment having the above configuration, since the oxygen-containing gas can be supplied to the chamber 10 after the cleaning gas is supplied, even if the inside of the chamber is repeatedly cleaned with the cleaning gas, particles of the metal compound generated by the cleaning gas are less likely to be generated. It is considered that this is because the metal compound produced by the reaction between the chamber 10 and the cleaning gas is partially oxidized by the oxygen-containing gas.

In the CVD apparatus 100 of the present embodiment, in the configuration in which it has a source gas supply pipe 35 for supplying the source gas to the chamber 10, and the source gas supply pipe 35, the cleaning gas supply pipe 40, and the oxygen-containing gas supply pipe 50 are connected to the chamber 10 via the gas supply pipe 30, respectively, since the flow paths of the source gas and the cleaning gas inside the chamber 10 are the same, the efficiency of removing the deposits of the film components generated at the time of film formation tends to be improved. Further, since the flow paths of the cleaning gas and the oxygen-containing gas are the same, the effect of suppressing the generation of particles of the metal compound generated by the cleaning gas tends to be improved.

In the CVD apparatus 100 of the present embodiment, in the configuration in which the cleaning gas supply pipe 40 includes an RPU 60, since the cleaning gas is activated and the cleaning power becomes higher, the efficiency of removing deposits of film components generated during film formation tends to be improved. Further, in the configuration in which the oxygen-containing gas supply pipe 50 includes an RPU 60, since the oxygen-containing gas is activated and the oxidizing power becomes higher, the effect of suppressing the generation of particles of the metal compound generated by the cleaning gas tends to be improved.

In the CVD apparatus 100 of the present embodiment, when the oxygen-containing gas contains oxygen and an inert gas, it tends to be easy to partially oxidize the metal compound produced by the cleaning gas. Further, when the oxygen concentration of the oxygen-containing gas is in the range of 40% by volume or more and 60% by volume or less, the metal compound tends to be more easily oxidized.

In the CVD apparatus 100 of the present embodiment, when the cleaning gas is a fluorine-containing gas, the efficiency of removing deposits of film components generated during film formation tends to be further improved. Further, when the fluorine-containing gas contains a fluorine compound gas and an inert gas, the amount of metal compounds produced by the reaction of the metal with the cleaning gas inside the chamber 10 tends to decrease.

In the CVD apparatus 100 of the present embodiment, when the gas discharge port 91 is arranged along the inner wall surface of the chamber 10, the cleaning gas easily flows along the inner wall surface of the chamber 10. Therefore, the efficiency of removing the deposits of the film components deposited on the inner wall surface of the chamber 10 at the time of film formation tends to be improved.

Further, according to the method for cleaning the chamber 10 of the CVD apparatus 100 of the present embodiment, since the step of supplying the oxygen-containing gas to the chamber 10 is performed after performing the step of supplying the cleaning gas to the chamber 10, even if the inside of the chamber is repeatedly cleaned with the cleaning gas, particles of the metal compound generated by the cleaning gas are less likely to be generated.

According to the method for cleaning the chamber 10 of the CVD apparatus 100 of the present embodiment, when the oxygen-containing gas in the step of supplying the oxygen-containing gas is supplied at a flow rate higher than the flow rate of the cleaning gas in the step of supplying the cleaning gas, oxidation of the metal compound generated by the cleaning gas tends to proceed uniformly, and the effect of suppressing the generation of particles tends to be improved.

According to the method for cleaning the chamber 10 of the CVD apparatus 100 of the present embodiment, when the oxygen-containing gas is supplied for 50% or less of the supply time of the cleaning gas, since excessive oxidation of the metal compound generated by the cleaning gas is suppressed, particles of the metal oxide tend to be less likely to be generated.

The embodiments of the present disclosure have been described so far with reference to the drawings. The present disclosure is not limited to the above-described embodiment, and can be appropriately modified without departing from the technical idea of the present disclosure. For example, in the present embodiment, the opening and closing of the first valve 41 and the second valve 51 is controlled by using the controller 70, but the present disclosure is not limited to this. For example, the first valve 41 and the second valve 51 may be opened and closed manually.

Further, in the present embodiment, the cleaning gas supply pipe 40 and the oxygen-containing gas supply pipe 50 are connected to the same RPU 60, respectively, and the cleaning gas and the oxygen-containing gas are supplied to the chamber 10 by the same path, but the present disclosure is not limited to this. For example, the cleaning gas supply pipe 40 and the oxygen-containing gas supply pipe 50 may be connected to different RPUs, or the cleaning gas and the oxygen-containing gas may be supplied to the chamber 10 by different paths.

Further, in the present embodiment, the chamber 10 is cleaned with the susceptor 80 lowered, but the present disclosure is not limited to this. For example, the chamber 10 may be cleaned with the susceptor 80 raised.

Further, in the present embodiment, the gas discharge port 91 is arranged along the inner wall surface of the chamber 10, but the present disclosure is not limited to this. For example, the gas discharge port 91 may be arranged around the support rod 82 of the susceptor 80 at the bottom of the chamber 10.

### Example 1

A CVD apparatus 100 having the configuration shown in FIG. 1 was prepared. The materials of the chamber body 11 of the chamber 10, the lid material 19, the shower head 20, the mounting plate 81 of the susceptor 80, and the support rod 82 are each made of aluminum. The inner diameter of the chamber 10 is 425 mm and the capacity is 15 L.

(Film Formation)

The substrate 1 to be processed was placed on the mounting plate 81 of the susceptor 80, and a thin film was formed on the surface of the substrate 1 to be processed by the CVD method. A silicon wafer was used as the substrate 1 to be processed, and an organosilane-based material was used as the source gas. After the film formation, the susceptor 80 was lowered to take out the substrate 1 to be processed from the chamber 10.

(Cleaning)

With the susceptor 80 lowered, the first valve 41 was opened, and plasma-generated cleaning gas (NF₃) was supplied to the inside of the chamber 10 at a flow rate of 0.5 slpm for 30 seconds. After that, with the first valve 41 closed, the second valve 51 is opened, and the inside of the chamber 10 was cleaned with the oxygen-containing gas (oxygen/argon, oxygen concentration: 50% by volume) plasma-generated as the oxygen amount at a flow rate of 2 slpm for 5 seconds.

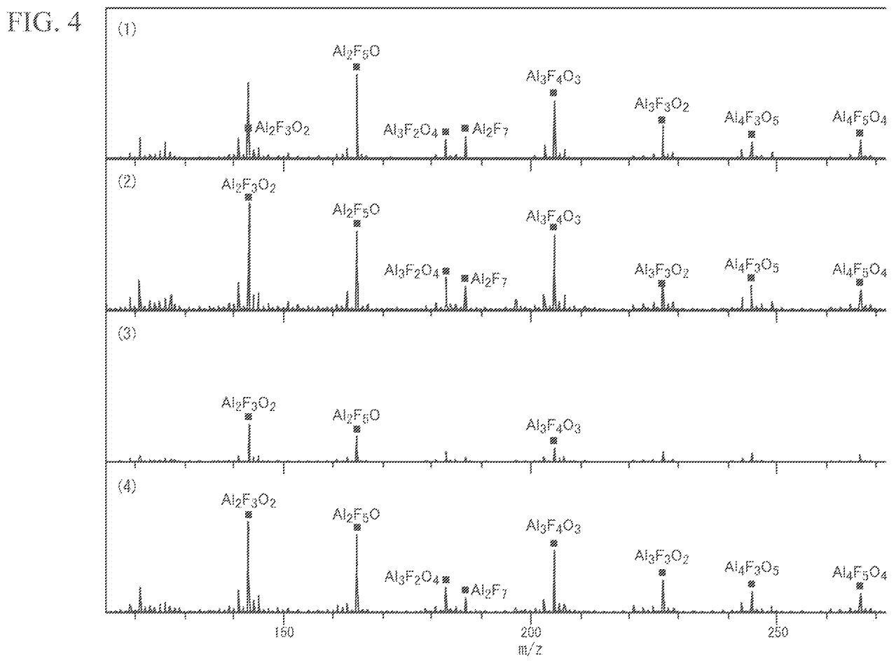

1000 cycles were carried out, with the operation of performing film formation once and cleaning once as one cycle. After that, (1) deposits adhering to the surface around the ventilation hole 21 of the shower head 20, (2) deposits adhering to the side surface of the gas exhaust pipe 90, (3) deposits adhering to the circumference of the support rod 82 of the susceptor 80 on the bottom surface of the chamber 10, and (4) deposits adhering to the periphery of the gas exhaust pipe 90 at the bottom surface of the chamber 10 were taken out, and the deposits were elementally analyzed using TOF-SIMS (time-of-flight secondary ion mass spectrometry). The result (mass spectrum) is shown in FIG. 4. As shown in the mass spectrum of FIG. 4, aluminum fluoride oxide was detected in each of the deposits at each of the locations (1) to (4). Moreover, when the surface of the thin film obtained by the film formation at the 1000th cycle was observed, no particles were observed on the surface of the thin film. It is considered that the reason why the particles were not generated is that the adhesion with aluminum constituting the base material was improved because the aluminum fluoride produced by the cleaning gas was partially oxidized by the oxygen-containing gas to form a passivation film containing fluoride oxide on the surface.

### Comparative Example 1

In the cleaning of Example 1, the same procedure as in Example 1 was carried out except that the oxygen-containing gas was not supplied after the plasma-generated cleaning gas was supplied to the inside of the chamber 10, 1000 cycles were carried out, with the operation of performing film formation once and cleaning once as one cycle. Then, in the same manner as in Example 1, the deposits adhering at each of the locations (1) to (4) were elementally analyzed. As a result, the deposits at each of the locations (1) to (4) were all aluminum fluoride. Moreover, when the surface of the thin film obtained by the film formation at the 1000th cycle was observed, slight adhesion of particles was observed on the surface of the thin film. From this result, it was confirmed that the aluminum fluoride has low adhesion to aluminum constituting the base material and is easily desorbed from the aluminum.

What is claimed is:

1. A CVD apparatus, comprising:
a chamber;
a cleaning gas supply pipe that supplies a cleaning gas to the chamber; and
an oxygen-containing gas supply pipe that supplies an oxygen-containing gas to the chamber,
wherein the cleaning gas supply pipe has a first valve,
the oxygen-containing gas supply pipe has a second valve,
after the first valve is opened to supply the cleaning gas to the inside of the chamber, the second valve is opened to supply the oxygen-containing gas to the inside of the chamber with the first valve closed.

2. The CVD apparatus according to claim 1, further comprising;
a source gas supply pipe that supplies a source gas to the chamber,
wherein the source gas supply pipe, the cleaning gas supply pipe, and the oxygen-containing gas supply pipe are each connected to the chamber via a gas supply pipe.

3. The CVD apparatus according to claim 1,
wherein the cleaning gas supply pipe and the oxygen-containing gas supply pipe include a remote plasma unit.

4. The CVD apparatus according to claim 1,
wherein the oxygen-containing gas contains oxygen and an inert gas.

5. The CVD apparatus according to claim 1,
wherein the oxygen concentration of the oxygen-containing gas is in the range of 40% by volume or more and 60% by volume or less.

6. The CVD apparatus according to claim 1,
wherein the cleaning gas is a fluorine-containing gas.

7. The CVD apparatus according to claim 6,
wherein the fluorine-containing gas contains a fluorine compound gas and an inert gas.

8. The CVD apparatus according to claim 1,
wherein a gas outlet is arranged along the inner wall surface of the chamber.

9. A method for cleaning a chamber of a CVD apparatus, including the following steps;
a step of supplying a cleaning gas to the chamber;
a step of stopping the supply of the cleaning gas to the chamber and supplying the oxygen-containing gas to the chamber.

10. The method for cleaning a chamber of CVD apparatus according to claim 9,
the oxygen-containing gas is supplied at a flow rate equal to or higher than the flow rate of the cleaning gas.

11. The method for cleaning a chamber of CVD apparatus according to claim 9, the oxygen-containing gas is supplied for 50% or less of the supply time of the cleaning gas.
